(19) United States
(12) Patent Application Publication
(10) Pub. No.: US 2004/0169520 A1
(43) Pub. Date: Sep. 2, 2004

(54) Methods and apparatus for testing optical and electrical components

(76) Inventors: Julia Y. Larikova, Bolingbrook, IL (US); Yajun Wang, Naperville, IL (US)

Correspondence Address: Cheryl F. Benes, Tellabs Operations, Inc., MS 16, 1415 West Diehl Road, Naperville, IL, 60563, US

(21) Appl. No.: 10/737,392

(22) Filed: Dec. 16, 2003

Related U.S. Application Data
(60) Provisional application No. 60/433,701, filed on Dec. 16, 2002.

(51) Int. Cl. G01R 31/308

(52) U.S. Cl. 324/753

(57) ABSTRACT

A method for testing a test component connected to a high-speed electrical component includes connecting a golden optical component to a high-frequency probe, connecting the high-frequency probe to the high-speed electrical component, operating the test component in an application environment to cause a transmission of a high-speed electrical signal from the high-speed electrical component to the golden optical component, and determining if the golden optical component responds to the high-speed electrical signal.

### RELATED APPLICATIONS

This application claims the benefit of U.S. Provisional Application No. 60/433,701, filed on Dec. 16, 2002, entitled “METHODS AND APPARATUS FOR TESTING OPTICAL AND ELECTRICAL COMPONENTS”.

### FIELD OF THE INVENTION

The present invention relates to testing of optical and electrical components. More specifically, the present invention relates to testing optical and electrical components on a substrate or platform such as PCB in an application environment at time of assembly (e.g. creation of a product) or even a re-assembly (e.g. refurbishment of a product).

### BACKGROUND OF THE INVENTION

Opto-electronic manufacturing has certain challenges. There are numerous problems due to the complex and delicate nature of optical components. These problems include long manual assembly times, rigorous photonics training of both manufacturing technicians and engineers, complicated and costly test systems, inability to reuse printed circuit boards (PCBs) because faulty optical components have been soldered onto them, and difficulty in isolating problems either at the optical component or on the PCB.

There are existing methods used for testing in opto-electronic manufacturing. However existing methods typically only test either the optical component or the PCB individually or do not completely simulate the application environment. For example, two methods that typically test only electrical components on PCB are the In-Circuit Test (ICT) and Boundary Scan Test (Bscan) (as described in the IEEEE JTAG 1149.1 standard).

### SUMMARY OF THE INVENTION

An apparatus for testing a component of unknown quality located on an application PCB includes a holder removably connected to the application PCB, adapted to hold a golden optical component, adapted to hold a high-frequency probe which connects the golden optical component to a high-speed electrical component located on the application PCB.

A method for testing a component of unknown quality located on an application PCB includes placing a golden optical-to-electrical converter in a holder, connecting the holder to the application PCB, connecting a high-speed electrical component located on the application PCB to the golden optical-to-electrical converter, transmitting a high-speed electrical signal from the golden optical-to-electrical converter to the high-speed electrical component, evaluating an operation of the component after the high-speed electrical component receives the high-speed electrical signal, and disconnecting the holder from the application PCB.

A method for testing a component of unknown quality located on an application PCB includes placing a golden electrical-to-optical converter in a holder, connecting the holder to the application PCB, connecting a high-speed electrical component located on the application PCB to the golden electrical-to-optical converter, transmitting a high-speed electrical signal from the high-speed electrical component to the golden electrical-to-optical converter, and evaluating a response of the golden electrical-to-optical converter to the high-speed electrical signal, and disconnecting the holder from the application PCB.

### DESCRIPTION OF THE DRAWINGS

The present invention is illustrated by way of example and not by way of limitation in the figures of the accompanying drawings, in which like references indicate similar elements and in which:

FIG. 1 is an apparatus in an environment for testing optical and electrical components on a PCB, according to an exemplary embodiment of the present invention; and

FIG. 2 is a double-spring loaded probe, according to an exemplary embodiment of the present invention.

### DETAILED DESCRIPTION

The inventors have recognized that a very helpful manufacturing test is one that completely simulates the application environment, such as testing both the optical component and the printed circuit board (PCB) as if the optical component were permanently affixed to the PCB. In the case where an application includes an optical-to-electrical converter (such as a photodiode) on a PCB, the test could include transmitting to the PCB electrical signals that emulate the output of the optical-to-electrical converter. In the case where an application includes an electrical-to-optical converter (such as a laser), the test could include transmitting to the electrical-to-optical converter electrical signals that emulate the output of a laser driver on the PCB (such as an integrated circuit (IC)). An exemplary test could be generating un-attenuated uA-currents modulated at high-speed rates of e.g. 10 GHz (to simulate what would be generated by an optical-to-electrical converter) and deliver the uA-currents to the pads of an IC on the PCB.

One way to implement the test of generating un-attenuated uA-currents modulated at high-speed rates to a PCB is to generate and deliver the uA-currents through a function generator and high-speed coaxial probes. However, this implementation may lose power exponentially and contribute background noise that exceeds the maximum tolerable Signal-to-Noise Ratio (SNR) requirement of the particular application.

Another way to implement the test of generating un-attenuated uA-currents modulated at high-speed rates to a PCB is to temporarily mount an optical component onto the PCB for the duration of the test. Soldering the optical component to the pads on the PCB is not the best way to implement the test because the pads on the PCB typically are not durable enough to withstand more than two to three re-solderings. Existing conductive and dissolvable glues to temporarily mount the optical component to the PCB are often not effective because they typically do not adhere or conduct current well. Directly placing the optical component on top of the pads on the PCB without assistance often does not maintain a good (e.g. zero-Ohms) connection because leads of an optical component are often delicate, making it difficult to achieve zero mechanical tolerance.

The present invention implements the test of generating high-speed electrical signals to and from a PCB by creating a test apparatus that is removably connected to an optical component, removably connects the optical component to the PCB, and maintains conductivity between the optical component and the PCB. By removably connecting an optical component and by being removably connected to the PCB, the present invention provides the benefit of reuse and interchangeability of the test apparatus, optical component and PCB.

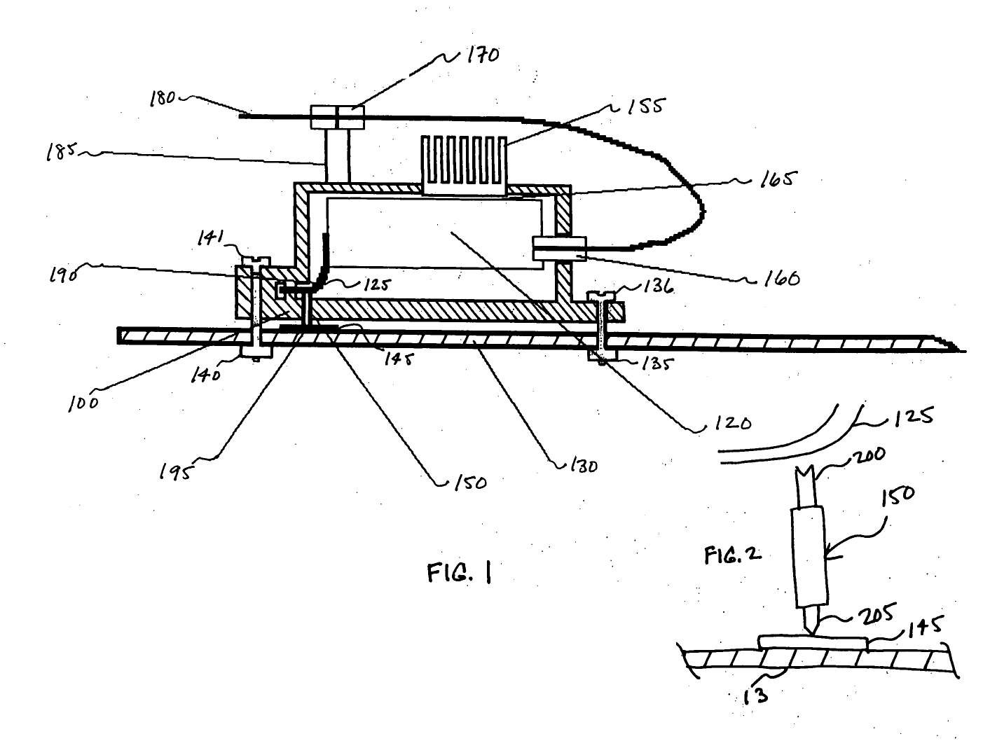

FIG. 1 shows an exemplary embodiment of the present invention. Test apparatus 100 holds an optical component 120. Test apparatus 100 is secured to a PCB 130 by connectors (nut 135, bolt or screw 136, nut 140, bolt or screw 141). Optical component 120 includes a lead 125. PCB 130 includes a pad 145 for a high-speed electrical component on the PCB (not shown). A probe 150 connects lead 125 to pad 145. Optionally, heat sink 155 may be attached to optical component 120 through a thermal pad 165. (If a heat sink is not used, test time may be limited.)

According to an exemplary embodiment, test apparatus 100 is made of material G10. However, other materials that may be used are those that maintain the x-y-z positions of the probes and have thermo-conductive properties to maintain normal operating conditions for the optical component held by the test apparatus. Another exemplary material is Teflon.

FIG. 2 shows in detail probe 150, a high-frequency (e.g. up to 10 GHz) double spring-loaded probe manufactured by Everett Charles Technologies, according to an exemplary embodiment. However, the probe need only be the frequency required to generate electrical signals to the PCB or the optical component for the particular application. The springs in a double spring-loaded probe 150 help ensure contact between the lead 125 and one end of the probe 200 and between the pad 145 and the other end of the probe 205. Because a lead on an optical component is often flexible and may maintain contact with an end of a probe that is not spring-loaded, an exemplary embodiment may use a probe that is spring-loaded only at the end of the probe in contact with the pad.

One method of the present invention is a manufacturing test. In this test, a golden optical component is used to test components of unknown quality located on a PCB. (A “golden” component is one that is good or has been verified as operating according to product application requirements.) In this test, the golden optical component is placed into the test apparatus which is secured to the PCB. By using a golden optical component, the PCB component(s) may be tested for verification and/or sensitivity. In verifying the PCB component(s), the PCB component(s) is tested to evaluate if its operation leads to the generation of an optical signal by an optical component (in the case where the optical component is an electrical-to-optical converter) or if it can operate after the generation of an electrical signal (in the case where the optical component is an optical-to-electrical converter). In the case where the optical component is an optical-to-electrical converter, the sensitivity of the PCB component(s) can be tested, to evaluate how it responds to adjustments in electrical signals generated by the optical-to-electrical converter. Thus, in either verifying or testing the sensitivity of a PCB component(s), it is evaluated if it operates in the same manner as a golden PCB component(s) would operate in the same test situation.

When a golden optical-to-electrical converter is used in the manufacturing test, the PCB component(s) can be verified because the electrical signals generated by the golden optical-to-electrical converter have already been verified and are known. Thus, the golden optical-to-electrical converter can be eliminated as a source of a problem in the application and the other components of the application can be troubles hooted. In addition to verifying that the PCB component(s) works, the sensitivity of the PCB component(s) can be tested because the electrical signals generated by the golden optical-to-electrical converter are known.

When a golden electrical-to-optical converter is used in the manufacturing test, the PCB component(s) can be verified because the optical signals generated by the golden electrical-to-optical converter have already been verified and are known. Thus, the golden electrical-to-optical converter can be eliminated as a source of a problem in the application and the other components of the application can be troubleshooted.

Executing the manufacturing test can provide many advantages. For example, electrical failures in the PCB can be isolated and identified. Examples of these electrical failures include thermal problems in high-speed electronic components, cold-solder joints previously undetected by an ICT or an X-ray, and slight impedance mismatches between components. In addition, the manufacturing test can help identify operational PCBs prior to soldering optical components to them, reduce time and cost of electronic re-work, allow easy troubleshooting by a manufacturing technician, help eliminate a pile of unusable PCBs, identify trends on the Surface-Mount Technology (SMT) assembly line, and provide operational PCBs for a subsequent expensive and time-consuming optical functional test.

While the manufacturing test includes using a golden optical component to test a PCB component(s) of unknown quality, the reverse is a functional test where a golden PCB (PCB containing golden components) is used to test an optical component of unknown quality. In the functional test, an optical component of unknown quality is placed inside the test apparatus which is secured to a golden PCB. By using a golden PCB, the optical component may be tested for verification and/or sensitivity. In the case where the optical component is an electrical-to-optical converter, it can be verified by evaluating if it actually generates an optical signal. Furthermore, an electrical-to-optical converter can be tested for sensitivity by evaluating how it responds to adjustments in electrical signals it receives from the golden PCB. In other words, in either verifying or testing the sensitivity of an electrical-to-optical converter, it is evaluated if it responds to an electrical signal in the same manner as a golden electrical-to-optical converter would respond to an equivalent electrical signal.

When an electrical-to-optical converter is used in the functional test, it can be verified because the electrical signals it receives from the golden PCB have already been verified and are known. Thus, the golden PCB can be eliminated as a source of a problem in the application and the electrical-to-optical converter can be troubleshooted. In addition to verifying that the electrical-to-optical converter actually generates an optical signal, the sensitivity of the electrical-to-optical converter can be tested because the electrical signals it receives from the golden PCB are known.

In the foregoing description, the invention is described with reference to specific example embodiments thereof. It will, however, be evident that various modifications and changes may be made thereto, without departing from the broader spirit and scope of the present invention. The specification and drawings are accordingly to be regarded in an illustrative rather than in a restrictive sense.

What is claimed is:

1. An apparatus for testing in an application environment, comprising:
a high-frequency probe; and
a holder adapted to removably connect an optical component to the high-frequency probe and adapted to removably connect the high-frequency probe to an application substrate.

2. The apparatus of claim 1, wherein the holder comprises G10 material.

3. The apparatus of claim 1, wherein the holder comprises Teflon material.

4. The apparatus of claim 1, wherein the high-frequency probe is double-spring loaded.

5. The apparatus of claim 1, wherein the high-frequency probe is single-spring loaded.

6. A method for testing an optical component, comprising:
connecting the optical component to a high-frequency probe;
connecting the high-frequency probe to a golden high-speed electrical component;
transmitting a high-speed electrical signal from the golden high-speed electrical component to the optical component; and
identifying a response by the optical component to the high-speed electrical signal.

7. The method of claim 6, further comprising evaluating the response by the optical component.

8. The method of claim 6, further comprising adjusting the high-speed electrical signal.

9. The method of claim 7, wherein the step of evaluating the response by the optical component comprises determining if the optical component responds in substantially the same manner as a golden optical component would respond to a substantially equivalent high-speed electrical signal.

10. The method of claim 7, wherein the step of evaluating the response by the optical component comprises comparing if the response is substantially the same as a golden optical component response to a substantially equivalent high-speed electrical signal.

11. A method for testing a test component connected to a high-speed electrical component, comprising:
connecting a golden optical component to a high-frequency probe;
connecting the high-frequency probe to the high-speed electrical component;
operating the test component in an application environment to cause a transmission of a high-speed electrical signal from the high-speed electrical component to the golden optical component; and
determining if the golden optical component responds to the high-speed electrical signal.

12. The method of claim 11, further comprising evaluating a response by the golden optical component.

13. The method of claim 11, further comprising adjusting the high-speed electrical signal.

14. The method of claim 12, wherein the step of evaluating a response by the golden optical component comprises determining if the golden optical component responds in substantially the same manner as the golden optical component would respond to a substantially equivalent high-speed electrical signal caused by a golden test component operation.

15. The method of claim 12, wherein the step of evaluating a response by the golden optical component comprises comparing if the response is substantially the same as a second golden optical component response to a substantially equivalent high-speed electrical signal caused by a golden test component operation.

16. A method for testing a test component connected to a high-speed electrical component, comprising:
connecting a golden optical component to a high-frequency probe;
connecting the high-frequency probe to the high-speed electrical component;
transmitting a high-speed electrical signal from the golden optical component to the high-speed electrical component; and
identifying a response by the test component.

17. The method of claim 16, further comprising evaluating the response by the test component.

18. The method of claim 16, further comprising adjusting the high-speed electrical signal.

19. The method of claim 17, wherein the step of evaluating the response by the test component comprises determining if the test component responds in substantially the same manner as a golden test component would respond.

20. The method of claim 17, wherein the step of evaluating the response by the test component comprises comparing if the response is substantially the same as a golden test component response.
